(19) United States
(12) Patent Application Publication
(10) Pub. No.: US 2024/0385521 A1
(43) Pub. Date: Nov. 21, 2024

(54) PRIMER FOR SEMICONDUCTOR SUBSTRATE AND METHOD FOR FORMING A PATTERN

(71) Applicant: NISSAN CHEMICAL CORPORATION, Tokyo (JP)

(72) Inventors: Shuhei SHIGAKI, Toyama-shi (JP); Satoshi TAKEDA, Toyama-shi (JP); Wataru SHIBAYAMA, Toyama-shi (JP); Makoto NAKAJIMA, Toyama-shi (JP)

(73) Assignee: NISSAN CHEMICAL CORPORATION, Tokyo (JP)

(21) Appl. No.: 18/785,814

(22) Filed: Jul. 26, 2024

Related U.S. Application Data
(62) Division of application No. 17/043,821, filed on Sep. 30, 2020.

(30) Foreign Application Priority Data
Apr. 13, 2018 (JP) 2018-077668

(51) Int. Cl. G03F 7/075; B32B 27/28; G03F 7/11; G03F 7/20; H01L 21/027

(52) U.S. Cl. CPC G03F 7/0752; G03F 7/11; H01L 21/0274; B32B 27/283; G03F 7/2004; G03F 7/2059

(57) ABSTRACT

A surface modifier for a resist pattern, which is to be applied to a substrate prior to the formation of a resist pattern with a thickness of 0.10 μm or less on the substrate to thereby enhance the adhesion between the substrate and the resist pattern, including at least one member selected from among a compound represented by average compositional formula (1), a hydrolysate thereof and a hydrolytic condensate thereof: R¹ₐR²_{b}(OX)_{c}SiO_{(4-a-b-c)/2} (1), wherein: R¹ represents a —(CH₂)ₙY group; Y represents a cyclohexenyl group, etc.; n is an integer of 0-4; R² represents a monovalent C1-4 hydrocarbon group; X represents a hydrogen atom or a monovalent C1-4 hydrocarbon group; a is a numerical value of 1-2; b is a numerical value of 0-1; and c is a numerical value of 0-2, provided that a+b+c is not greater than 4.

### RELATED APPLICATIONS

The present application is a divisional application of application Ser. No. 17/043,821 filed Sep. 30, 2020, which is a U.S. national stage application of PCT/JP2019/015411 filed Apr. 9, 2019, claiming priority to Japanese Application No. 2018-077668 filed Apr. 13, 2018. Each of the prior application is incorporated herein by reference in its entirety.

### TECHNICAL FIELD

The present invention relates to a primer for a semiconductor substrate which is a surface modifier for a resist pattern, a laminated substrate in which the surface modifier and a resist pattern are laminated in this order on a substrate, a method for forming a pattern and a method for manufacturing a semiconductor device.

### BACKGROUND ART

In the manufacture of a semiconductor device, a lithography process using a resist composition has conventionally been carried out. In recent years, accompanied with high integration of the semiconductor device, miniaturization of patterns such as wiring has been required. Accompanied with miniaturization of patterns, far-ultraviolet light, vacuum ultraviolet light, electron beam (EB), X-rays, etc., having shorter wavelengths have been used as light sources. Particularly in recent years, it has been carried out that short-wavelength light such as KrF excimer laser (wavelength 248 nm) and ArF excimer laser (wavelength 193 nm) is employed to form a resist pattern.

Accompanied with this, diffused reflection of active rays from a semiconductor substrate or an effect of standing waves become great problems, and in order to solve the problems, it has widely been investigated a method in which an antireflection film (Bottom Anti-Reflective Coating: BARC) is provided between a resist and the semiconductor substrate. As such an antireflection film, a number of investigations have been carried out on an organic antireflection film formed from a composition containing a polymer having a light absorbing group (chromophore) from its ease of use, and the like (for example, Patent Literature 1).

On the other hand, in EUV (extreme ultraviolet radiation, wavelength 13.5 nm) applied to further fine processing technology, the problem of reflection from the semiconductor substrate does not occur, but resist pattern collapse accompanied by pattern miniaturization becomes a problem, so that investigation on a resist underlayer film having high adhesiveness to the resist is being carried out.

### CITATION LIST

Patent Literature 1: JP 2008-501985A

### SUMMARY OF INVENTION

### Technical Problem

In the conventional resist underlayer film, there are problems that etching failures such as side etching, etc., in the etching step are likely to occur. Accordingly, if modification of the surface of the substrate is possible by a primer layer having a thinner film thickness as compared with the conventional underlayer film, it can be expected to improve adhesion of the photoresist and to improve photoresist resolution in the advanced lithography process without generating etching failure such as side etching, etc.

The present invention has been made to improve the above-mentioned circumstances, and an object thereof is to provide a primer for a semiconductor substrate which is a novel surface modifier for a resist pattern having high adhesion to a resist film, and capable of forming a good resist pattern with a thin film, a laminated substrate in which the surface modifier and a resist pattern are laminated in order on a substrate, a method for forming a pattern and a manufacturing method of a semiconductor device.

### Solution to Problem

The present invention embraces the following.
[1] A surface modifier for a resist pattern, which is for being applied onto a substrate prior to formation of a resist pattern with 0.10 um or less on the substrate to enhance adhesion between the substrate and the resist pattern, comprising at least one species of
a compound represented by the following average compositional formula (1),
a hydrolysate of the compound represented by the following average compositional formula (1), and
a hydrolysis condensate of the compound represented by the following average compositional formula (1):

[Formula 1]

R¹ₐR²_{b}(OX)_{c}SiO_{(4-a-b-c)/2} (1)
wherein R¹ is a monovalent organic group represented by the general formula: —(CH₂)ₙY, in which Y represents a hydrogen atom, an acetoxy group, a γ-butyrolactone group, a C1 to C6 carbinol group which may be substituted with a halogen atom(s), a norbornene group, a tolyl group, C1 to C3 alkoxyphenyl group, a C6 to C30 aryl group which may be substituted with a halogen atom(s) or a C1 to C3 alkoxysilyl group, a C1 to C4 alkyl group which may be interrupted by an oxygen atom, a phenylsulfonamide group, a monovalent group derived from cyclic amide which may be substituted with a C1 to C3 alkyl group or a C2 to C5 alkenyl group, a monovalent group derived from cyclic imide which may be substituted with a C1 to C3 alkyl group or a C2 to C5 alkenyl group, a C3 to C6 cyclic alkenyl group which may be substituted with a C1 to C3 alkyl group or a C2 to C5 alkenyl group, a phenylsulfone group, a p-tolylsulfonyl group, a p-toluenesulfonyl group or a monovalent group represented by the following formula (1-1) or (1-2),

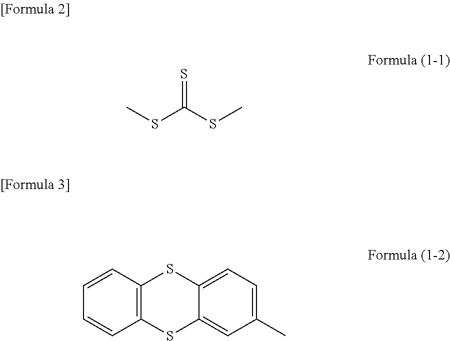

n is an integer of 0 to 4,
R² is a C1 to 4 monovalent hydrocarbon group,
X represents a hydrogen atom or a C1 to 4 monovalent hydrocarbon group,
a is a number of 1 to 2,
b is a number of 0 to 1,
c is a number of 0 to 2, and
a+b+c≤4.
[2] The surface modifier according to [1], wherein R¹ is an acetoxy group, a γ-butyrolactone group, a di(trifluoromethyl)hydroxymethyl group, a cyclohexenyl group, a tolyl group, a C1 to C3 alkoxyphenyl group, a pentafluorophenyl group, a phenanthrenyl group, a C1 to C3 alkoxysilylphenyl group, a phenylsulfonamide group, or a monovalent group represented by the following formula (1-1), (1-2) or (1-3):

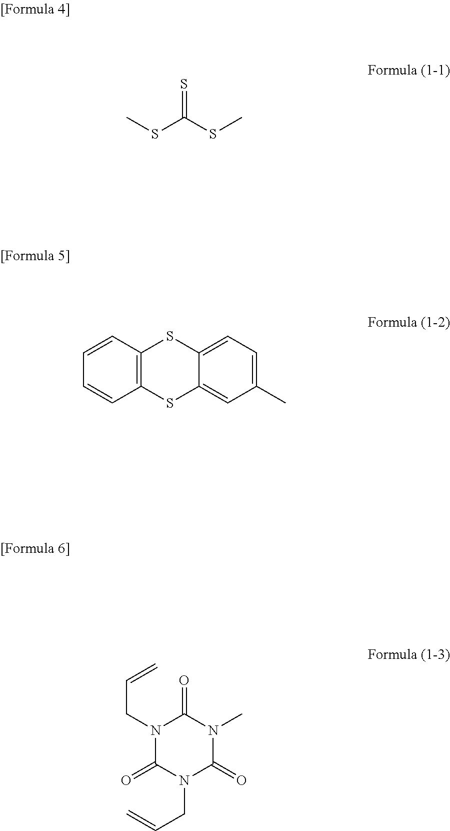

[3] The surface modifier according to [1] or [2], wherein the substrate is a metal or an inorganic-based antireflection film substrate.
[4] The surface modifier according to any one of [1] to [3], wherein the substrate contains Si, SiN, SiON, TiSi, TiN or glass which may be vapor-deposited by Cr.
[5] A laminated substrate, which comprises a substrate, the surface modifier according to any one of [1] to [4] laminated on the substrate, and a resist pattern laminated on the laminated surface modifier.
[6] The laminated substrate according to [5], which further comprises a silicon hard mask layer on the substrate.
[7] A method for forming a pattern, which comprises applying the surface modifier according to any one of [1] to [4] onto a substrate, baking the applied surface modifier, applying a photoresist composition onto the baked surface modifier and subjecting the photoresist composition-applied substrate to patterning.
[8] The method for forming a pattern according to [7], wherein the step of patterning comprises the step of exposing the photoresist composition-applied substrate with ArF, EUV or EB.
[9] A method for manufacturing a semiconductor device, which comprises the steps of applying the surface modifier according to any one of [1] to [4] onto a substrate, baking the applied surface modifier, applying a photoresist composition onto the baked surface modifier, subjecting the photoresist composition-applied substrate to patterning, and etching the patterned substrate.
[10] The laminated substrate according to [5], which further comprises spin-on carbon or amorphous carbon on the substrate, and a silicon hard mask layer further thereon.

### Advantageous Effects of Invention

According to the present invention, adhesiveness of the photoresist is improved by modification of the surface of the wafer by the silane coupling agent, and the photoresist resolution in the advanced lithography process is improved. In addition, the film thickness of the silane coupling agent is thinner than that of the conventional lower layer film, so that there is an advantage that etching failure such as side etching, etc., in the etching step difficultly occur.

That is, the conventional organic-based primer has weak bond with a substrate and bond between the primers, and is likely decomposed by moisture, but the compound represented by the average compositional formula (1), the hydrolysate thereof, or the hydrolysis condensate thereof according to the present invention is a Si-based, so that they have strong bond with a substrate and bond between the primers, and is difficultly decomposed by moisture. As a result, the surface modifier according to the present invention exerts high surface modifying ability due to strong adhesiveness with a substrate and improvement in adhesiveness by crosslinking between the primers.

In the present invention, when the surface modifier containing the compound represented by the average compositional formula (1) is applied, the formed coating film may thereafter be subjected to hydrolysis or hydrolysis condensation. Also, when the surface modifier containing a hydrolysate of the compound represented by the average compositional formula (1), the formed coating film may thereafter be subjected to hydrolysis condensation. In general, these manners would be able to make the baked film thinner than the film obtained by applying a surface modifier containing a hydrolysis condensate of the compound represented by the average compositional formula (1).

Further, in any of the coating films obtained from either of the surface modifiers, a final film thickness or the degree of surface modification may be controlled by changing the baking conditions, by the removal by a solvent, etc. In addition, in any of the coating films obtained from either of the surface modifiers, irrespective of the thickness of the film immediately after the application, the coating films still remain on the surface of the substrate after removal of the solvent, they have good uniformity in film thickness and exhibit excellent lithographic characteristics.

The coating film of the present application may be a monomolecular film of the compound represented by the average compositional formula (1).

Therefore, according to the present invention, it is possible to carry out surface treatment with a film thickness of, for example, about 0.1 nm to 5 nm (1 to 50 Å).

The surface modifier according to the present invention shows an advantageous effect of preventing collapse of the resist through its strong adhesiveness to the substrate and improvement in the adhesiveness due to crosslinking between the primers, and further various effects may be imparted thereto by appropriately selecting R¹ in the average compositional formula (1). For example, by selecting as R¹ a group that generates an acid by photolysis, it is possible to change the shape of the resist. Also, by selecting as R¹ a group that becomes hydrophilic by photolysis or by thermal decomposition, it is also possible to change the shape of the resist. Also, by selecting as R¹ a group that generates a base by photolysis, it is possible to strengthen the preventing effect of the resist collapse. Further, by selecting as R¹ a group that makes the substrate hydrophobic, it is possible to obtain an effect of preventing pattern collapse.

The degree of surface modification by the surface modifier according to the present invention may be evaluated, for example, by measuring the water contact angle by the method described in Examples. The larger the difference between the water contact angles before and after the application, the larger the degree of surface modification.

The surface modifier according to the present invention may be used not only as a surface treatment agent, but also as a film that functions as an etching mask for a semiconductor substrate.

The surface modifier according to the present invention may be applied not only onto a glass substrate, but also onto Bare-Si and other oxide films and nitride films such as SiO₂, SiN, SiON, TiN, etc., and metal substrates. Further, it may also be applied onto a coating-type or a vapor deposition-type SiHM (silicon hard mask), onto BARC, onto a coating-type SOC (spin-on carbon, a film having a high carbon content) or onto a vapor deposition-type carbon film (amorphous carbon film, etc.).

The surface modifier according to the present invention may be applied to form a resist pattern by a short wavelength light such as ArF, electron beam (EB), extreme ultraviolet (EUV), etc.

### BRIEF DESCRIPTION OF DRAWINGS

FIG. 1 is an SEM photograph showing a result of forming a primer layer and a photoresist on SiON, exposing the same using an EUV exposure machine, and patterning the same.

FIG. 2 is an SEM photograph showing a result of forming a primer layer and a photoresist on SiON, exposing the same using an EUV exposure machine, and patterning the same.

FIG. 3 is an SEM photograph showing a result of forming a photoresist on SiON without forming a primer layer, exposing the same using an EUV exposure machine, and patterning the same.

FIG. 4 is an SEM photograph showing a result of forming a primer layer and a photoresist on SiON, exposing the same using an EUV exposure machine, and subjecting the same to drawing using an EB drawing machine.

FIG. 5 is an SEM photograph showing a result of forming a primer layer and a photoresist on SiON, and subjecting the same to drawing using an EB drawing machine.

FIG. 6 is an SEM photograph showing a result of forming a photoresist on SiON without forming a primer layer, and subjecting the same to drawing using an EB drawing machine.

### DESCRIPTION OF EMBODIMENTS

### Surface Modifier

The present invention relates to a surface modifier for a resist pattern, which is for being applied onto a substrate prior to formation of a resist pattern with 0.1 μm or less, preferably 0.05 μm or less on the substrate to enhance adhesion between the substrate and the resist pattern.

The surface modifier according to the present invention contains at least one species of
a compound represented by the following average compositional formula (1),
a hydrolysate of the compound represented by the following average compositional formula (1), and
a hydrolysis condensate of the compound represented by the following average compositional formula (1).

[Formula 7]

R¹ₐR²_{b}(OX)_{c}SiO_{(4-a-b-c)/2} (1)
(wherein R¹ is a —(CH₂)ₙY group,
Y represents a hydrogen atom, an acetoxy group, a γ-butyrolactone group, a C1 to C6 carbinol group which may be substituted with a halogen atom(s), a norbornene group, a tolyl group, C1 to C3 alkoxyphenyl group, a C6 to C30 aryl group which may be substituted with a halogen atom(s) or a C1 to C3 alkoxysilyl group, a C1 to C4 alkyl group which may be interrupted by an oxygen atom, a phenylsulfonamide group, a cyclic amide group which may be substituted with a C1 to C3 alkyl group or a C2 to C5 alkenyl group, a cyclic imide group which may be substituted with a C1 to C3 alkyl group or a C2 to C5 alkenyl group, a C3 to C6 cyclic alkenyl group which may be substituted with a C1 to C3 alkyl group or a C2 to C5 alkenyl group, a phenylsulfone group, a tolylsulfone group or a monovalent group represented by the following formula (1-1) or (1-2),

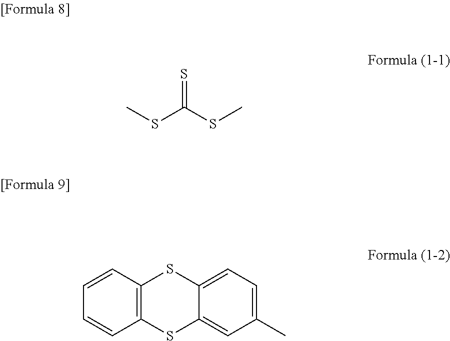

n is an integer of 0 to 4,
R² is a C1 to 4 monovalent hydrocarbon group,
X represents a hydrogen atom or a C1 to 4 monovalent hydrocarbon group,
a is a number of 1 to 2,
b is a number of 0 to 1,
c is a number of 0 to 2, and
a+b+c≤4.)

The molecular weight of the compound represented by the average compositional formula (1) ranges, for example, from 100 to 999.

The typical alkyl group in the above-mentioned “C1 to C4 alkyl group which may be interrupted by an oxygen atom”, “cyclic amide group which may be substituted with a C1 to C3 alkyl group or a C2 to C5 alkenyl group”, “cyclic imide group which may be substituted with a C1 to C3 alkyl group or a C2 to C5 alkenyl group”, “cyclic alkenyl group which may be substituted with a C1 to C3 alkyl group or a C2 to C5 alkenyl group” is an alkyl group which is linear or branched and has 1 to 3 or 1 to 4 carbon atoms. It includes, for example, a methyl group, an ethyl group, an n-propyl group, an i-propyl group, etc. Also, a cyclic alkyl group may also be used, and it includes, for example, a cyclopropyl group, etc.

The C1 to C4 alkyl group interrupted by an oxygen atom includes a methoxymethyl group, a methoxyethyl group, a methoxypropyl group, an ethoxymethyl group, an ethoxyethyl group, etc.

The C2 to C5 alkenyl group includes an allyl group, a vinyl group (an ethenyl group), a propenyl group and a butenyl group, and preferably an allyl group.

The monovalent group derived from a cyclic amide includes a monovalent group derived from an α-lactam (three-membered ring), β-lactam (four-membered ring), γ-lactam (five-membered ring) or δ-lactam (six-membered ring).

The monovalent group derived from a cyclic imide includes, for example, an isocyanuric group. The monovalent group derived from a cyclic imide is preferably an isocyanuric group having a hydrogen atom, a methyl group or a C2 to C5 alkenyl group as substituents on the nitrogen atoms at the 2 and 4-positions.

More preferably, it is a monovalent group having a structure of the following formula (1-3).

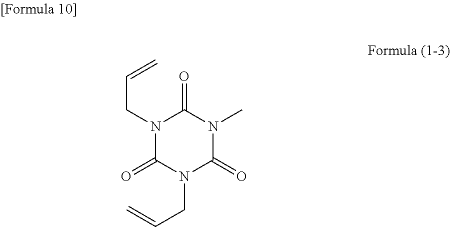 [SMILES: C=CCn1c(=O)n(C)c(=O)n(CC=C)c1=O]

The typical cyclic alkenyl group in the above-mentioned “C3 to C6 cyclic alkenyl group which may be substituted with a C1 to C3 alkyl group or a C2 to C5 alkenyl group” includes a 1-cyclopentenyl group, a 2-cyclopentenyl group, a 3-cyclopentenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group and a 3-cyclohexenyl group, etc.

The “cyclic alkenyl group which may be substituted with a C1 to C3 alkyl group or a C2 to C5 alkenyl group” includes, for example, the above-mentioned cyclic alkenyl group, one of the hydrogen atom of which is substituted with the above-mentioned C1 to C3 alkyl group or C2 to C5 alkenyl group, etc.

The typical aryl group in the above-mentioned “C6 to C30 aryl group which may be substituted with a halogen atom(s) or a C1 to C3 alkoxysilyl group” includes an aryl group having 6 to 30 carbon atoms, and includes, for example, phenyl group, an o-methylphenyl group, a m-methylphenyl group, a p-methylphenyl group, an o-chlorophenyl group, a m-chlorophenyl group, a p-chlorophenyl group, an o-fluorophenyl group, a pentafluorophenyl group, a p-mercaptophenyl group, an o-methoxyphenyl group, a p-methoxyphenyl group, a p-aminophenyl group, a p-cyanophenyl group, an α-naphthyl group, a β-naphthyl group, an o-biphenylyl group, a m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group and a 4-triethoxysilylphenyl group, etc. The typical alkoxy group in the above-mentioned “C1 to C3 alkoxyphenyl group” and “C6 to C30 aryl group which may be substituted with a halogen atom(s) or a C1 to C3 alkoxysilyl group” includes an alkoxy group having a linear, branched or cyclic alkyl portion with 1 to 3 carbon atoms, and it includes, for example, methoxy group, an ethoxy group, an n-propoxy group, an i-propoxy group, etc., and the cyclic alkoxy group includes a cyclopropoxy group, etc.

The “C1 to C3 alkoxyphenyl group” includes, for example, a 4-methoxyphenyl group, a 4-ethoxyphenyl group, a 4-(methoxymethoxy)phenyl group, a 4-(1-methoxyethoxy)phenyl group, etc.

The typical halogen atom in the above-mentioned “C1 to C6 carbinol group which may be substituted with a halogen atom(s)” and “C6 to C30 aryl group which may be substituted with a halogen atom(s) or a C1 to C3 alkoxysilyl group” includes fluorine, chlorine, bromine, iodine, etc.

The C1 to C6 carbinol group which may be substituted with a halogen atom(s) includes a di(trifluoromethyl)hydroxymethyl group, a 1,1-di(trifluoromethyl)-1-hydroxyethyl group, etc.

Preferable R¹ includes an acetoxy group, a γ-butyrolactone group, a di(trifluoromethyl)hydroxymethyl group, a cyclohexenyl group, a tolyl group, a C1 to C3 alkoxyphenyl group, a pentafluorophenyl group, a phenanthrenyl group, a C1 to C3 alkoxysilylphenyl group, a phenylsulfonamide group, or a monovalent group represented by the following formula (1-1), (1-2) or (1-3)

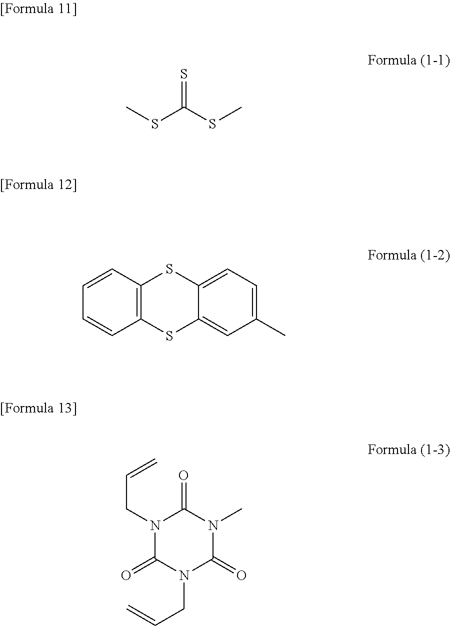

R² is a C1 to 4 monovalent hydrocarbon group, specifically a linear or branched alkyl group having 1 to 4 carbon atoms, and it includes, for example, a methyl group, an ethyl group, an n-propyl group, an i-propyl group, etc.

The compound represented by the average compositional formula (1), the hydrolysate thereof, and the hydrolysis condensate thereof may be one species or two or more species, respectively. One species or two or more species from each of the compound represented by the average compositional formula (1), the hydrolysate thereof, and the hydrolysis condensate may be used in combination. Use of one species or two species is preferable.

An exemplary combination in which two species thereof are combined is a combination of
(1a) a compound represented by the above-mentioned average compositional formula (1) wherein Y has a tolyl group, a C1 to C3 alkoxyphenyl group, a C6 to C30 aryl group which may be substituted with a halogen atom(s) or a C1 to C3 alkoxysilyl group, a phenylsulfonamide group, a monovalent group derived from cyclic amide which may be substituted with a C1 to C3 alkyl group or a C2 to C5 alkenyl group, a monovalent group derived from cyclic imide which may be substituted with a C1 to C3 alkyl group or a C2 to C5 alkenyl group, and
(2a) a compound represented by the above-mentioned average compositional formula (1) wherein Y has a phenylsulfonamide group, a phenylsulfone group, a p-tolylsulfonyl group, a p-toluenesulfonyl group or a monovalent group represented by the following formula (1-1) or (1-2).

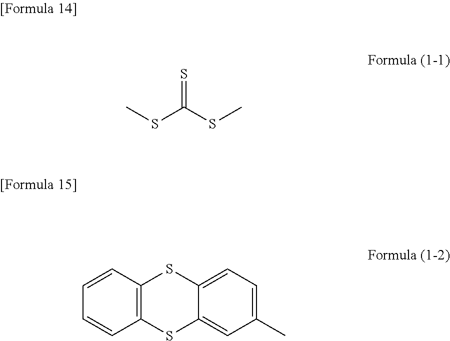

An exemplary combination in which two or more species are combined is a combination of
(1a) a compound represented by the above-mentioned average compositional formula (1) wherein Y has a monovalent group derived from cyclic amide which may be substituted with a C2 to C5 alkenyl group, and
(2a) a compound represented by the above-mentioned average compositional formula (1) wherein Y has a phenylsulfonamide group, a phenylsulfone group, a p-tolylsulfonyl group, a p-toluenesulfonyl group or a monovalent group represented by the following formula (1-1) or (1-2).

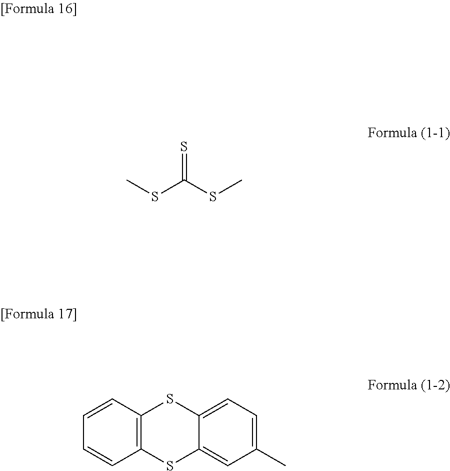

An exemplary combination in which two or more species are combined is a combination of
(1a) a compound represented by the above-mentioned average compositional formula (1) wherein Y has an isocyanuric group which is a C2 to C5 alkenyl group, and
(2a) a compound represented by the above-mentioned average compositional formula (1) wherein Y has a phenylsulfonamide group, a phenylsulfone group, a p-tolylsulfonyl group, a p-toluenesulfonyl group or a monovalent group represented by the following formula (1-1) or (1-2).

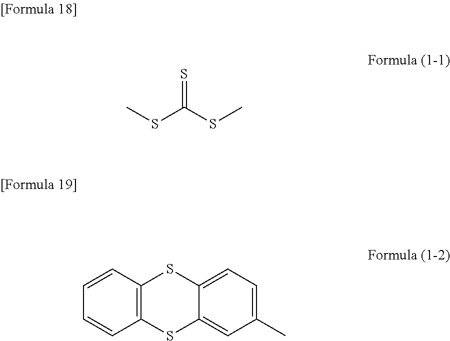

An exemplary combination in which two or more species are combined is a combination of
(1a) a compound represented by the above-mentioned average compositional formula (1) wherein the above-mentioned R¹ has a γ-butyrolactone group, a di(trifluoromethyl)hydroxymethyl group, a cyclohexenyl group, a tolyl group, a C1 to C3 alkoxyphenyl group, a pentafluorophenyl group, a phenanthrenyl group, a C1 to C3 alkoxysilylphenyl group, a phenylsulfonamide group or a monovalent group represented by the following formula (1-3), and

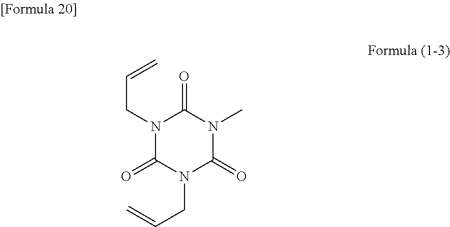 [SMILES: C=CCn1c(=O)n(C)c(=O)n(CC=C)c1=O]

(2a) a compound represented by the above-mentioned average compositional formula (1) wherein the above-mentioned R¹ has a phenylsulfonamide group or a monovalent group represented by the following formula (1-1) or (1-2).

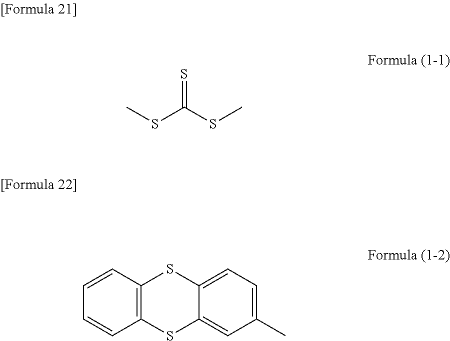

### Hydrolysate

The hydrolysate of the compound represented by the average compositional formula (1) may generally be obtained by hydrolysis of the compound by a known method. One of the most widely known methods is a hydrolysis method in which pure water or a mixed solvent of pure water and a solvent is added to a solution of the compound represented by the average compositional formula (1) dissolved in a solvent by a method of dropwise addition, etc., and the mixture is heated and stirred at a temperature of 40° C. or higher for several hours or longer. The amount of pure water used in this method may be arbitrarily selected depending on the purpose of complete hydrolysis and partial hydrolysis. Water is usually used in an amount of 0.5 to 100 mol, preferably 1 to 10 mol based on all the alkoxy groups of the compound represented by the average compositional formula (1). The hydrolysis may be carried out using a hydrolysis catalyst, or may also be carried out without using a hydrolysis catalyst. When the hydrolysis catalyst is used, 0.001 to 10 moles, preferably 0.001 to 1 mole of the hydrolysis catalyst may be used per mole of the hydrolyzable group. The reaction temperature for the hydrolysis and condensation usually ranges from 2 to 150° C. The hydrolysis may be carried out completely or partially. That is, a hydrolysate or a monomer may be remained in the hydrolysis condensate.

With reference to the above-mentioned hydrolysate, the compound represented by the average compositional formula (1), the hydrolysate thereof, and the hydrolysis condensate thereof may be one species or two or more species, respectively. One species or two or more species from each of the compound represented by the average compositional formula (1), the hydrolysate thereof, and the hydrolysis condensate may be used in combination. Use of one species or two species is preferable.

Specific examples of the combination of two species of the above-mentioned hydrolysates includes a combination of the compounds represented by the above-mentioned average compositional formula (1).

In the above-mentioned hydrolysis method, it is general to use an acid catalyst or an alkali catalyst to accelerate the hydrolysis reaction. As the hydrolysis catalyst, an acid or a base may be used. The hydrolysis catalyst also includes a metal chelate compound, an organic acid, an inorganic acid, an organic base and an inorganic base.

The metal chelate compound as the hydrolysis catalyst includes, for example, a titanium chelate compound such as triethoxy-mono(acetylacetonate)titanium, tri-n-propoxy-mono(acetylacetonate)titanium, tri-i-propoxy-mono(acetylacetonate)titanium, tri-n-butoxy-mono(acetylacetonate)titanium, tri-sec-butoxy-mono(acetylacetonate)titanium, tri-t-butoxy-mono(acetylacetonate)titanium, diethoxy-bis(acetylacetonate)titanium, di-n-propoxy-bis(acetylacetonate)titanium, di-i-propoxy-bis(acetylacetonate)titanium, di-n-butoxy-bis(acetylacetonate)titanium, di-sec-butoxy-bis(acetylacetonate)titanium, di-t-butoxy-bis(acetylacetonate)titanium, monoethoxy-tris(acetylacetonate)titanium, mono-n-propoxy-tris(acetylacetonate)titanium, mono-i-propoxy-tris(acetylacetonate)titanium, mono-n-butoxy-tris(acetylacetonate)titanium, mono-sec-butoxy-tris(acetylacetonate)titanium, mono-t-butoxy-tris(acetylacetonate)titanium, tetrakis(acetylacetonate)titanium, triethoxy-mono(ethyl acetoacetate)titanium, tri-n-propoxy-mono(ethyl acetoacetate)titanium, tri-i-propoxy-mono(ethyl acetoacetate)titanium, tri-n-butoxy-mono(ethyl acetoacetate)titanium, tri-sec-butoxy-mono(ethyl acetoacetate)titanium, tri-t-butoxy-mono(ethyl acetoacetate)titanium, diethoxy-bis(ethyl acetoacetate)titanium, di-n-propoxy-bis(ethyl acetoacetate)titanium, di-i-propoxy-bis(ethyl acetoacetate)titanium, di-n-butoxy-bis(ethyl acetoacetate)titanium, di-sec-butoxy-bis(ethyl acetoacetate)titanium, di-t-butoxy-bis(ethyl acetoacetate)titanium, monoethoxy-tris(ethyl acetoacetate)titanium, mono-n-propoxy-tris(ethyl acetoacetate)titanium, mono-i-propoxy-tris(ethyl acetoacetate)titanium, mono-n-butoxy-tris(ethyl acetoacetate)titanium, mono-sec-butoxy-tris(ethyl acetoacetate)titanium, mono-t-butoxy-tris(ethyl acetoacetate)titanium, tetrakis(ethyl acetoacetate)titanium, mono(acetylacetonate)tris(ethyl acetoacetate)titanium, bis(acetylacetonate)bis(ethyl acetoacetate)titanium, tris(acetylacetonate)mono(ethyl acetoacetate)titanium, etc.; a zirconium chelate compound such as triethoxy-mono(acetylacetonate)zirconium, tri-n-propoxy-mono(acetylacetonate)zirconium, tri-i-propoxy-mono(acetylacetonate)zirconium, tri-n-butoxy-mono(acetylacetonate)zirconium, tri-sec-butoxy-mono(acetylacetonate)zirconium, tri-t-butoxy-mono(acetylacetonate)zirconium, diethoxy-bis(acetylacetonate)zirconium, di-n-propoxy-bis(acetylacetonate)zirconium, di-i-propoxy-bis(acetylacetonate)zirconium, di-n-butoxy-bis(acetylacetonate)zirconium, di-sec-butoxy-bis(acetylacetonate)zirconium, di-t-butoxy-bis(acetylacetonate)zirconium, monoethoxy-tris(acetylacetonate)zirconium, mono-n-propoxy-tris(acetylacetonate)zirconium, mono-i-propoxy-tris(acetylacetonate)zirconium, mono-n-butoxy-tris(acetylacetonate)zirconium, mono-sec-butoxy-tris(acetylacetonate)zirconium, mono-t-butoxy-tris(acetylacetonate)zirconium, tetrakis(acetylacetonate)zirconium, triethoxy-mono(ethyl acetoacetate)zirconium, tri-n-propoxy-mono(ethyl acetoacetate)zirconium, tri-i-propoxy-mono(ethyl acetoacetate)zirconium, tri-n-butoxy-mono(ethyl acetoacetate)zirconium, tri-sec-butoxy-mono(ethyl acetoacetate)zirconium, tri-t-butoxy-mono(ethyl acetoacetate)zirconium, diethoxy-bis(ethyl acetoacetate)zirconium, di-n-propoxy-bis(ethyl acetoacetate)zirconium, di-i-propoxy-bis(ethyl acetoacetate)zirconium, di-n-butoxy-bis(ethyl acetoacetate)zirconium, di-sec-butoxy-bis(ethyl acetoacetate)zirconium, di-t-butoxy-bis(ethyl acetoacetate)zirconium, monoethoxy-tris(ethyl acetoacetate)zirconium, mono-n-propoxy-tris(ethyl acetoacetate)zirconium, mono-i-propoxy-tris(ethyl acetoacetate)zirconium, mono-n-butoxy-tris(ethyl acetoacetate)zirconium, mono-sec-butoxy-tris(ethyl acetoacetate)zirconium, mono-t-butoxy-tris(ethyl acetoacetate)zirconium, tetrakis(ethyl acetoacetate)zirconium, mono(acetylacetonate)tris(ethyl acetoacetate)zirconium, bis(acetylacetonate)bis(ethyl acetoacetate)zirconium, tris(acetylacetonate)mono(ethyl acetoacetate)zirconium, etc.; and an aluminum chelate compound such as tris(acetylacetonate)aluminum, tris(ethyl acetoacetate)aluminum, etc.; and the like.

The organic acid as the hydrolysis catalyst includes, for example, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linolic acid, linoleic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, tartaric acid, etc.

The inorganic acid as the hydrolysis catalyst includes, for example, hydrochloric acid, nitric acid, sulfuric acid, hydrofluoric acid, phosphoric acid, etc.

The organic base as the hydrolysis catalyst includes, for example, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, etc. The inorganic base includes, for example, ammonia, sodium hydroxide, potassium hydroxide, barium hydroxide, calcium hydroxide, etc. Of these catalysts, the metal chelate compound, the organic acid and the inorganic acid are preferable, and they may be used one species alone or two or more species in combination.

The organic solvent to be used for hydrolysis includes, for example, an

aliphatic hydrocarbon-based solvent such as n-pentane, i-pentane, n-hexane, i-hexane, n-heptane, i-heptane, 2,2,4-trimethylpentane, n-octane, i-octane, cyclohexane, methylcyclohexane, etc.; an aromatic hydrocarbon-based solvent such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, etc.; a monoalcohol-based solvent such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, cresol, etc.; a polyhydric alcohol-based solvent such as ethylene glycol, propylene glycol, 1,3-butylene glycol, pentanediol-2,4, 2-methylpentanediol-2,4, hexanediol-2,5, heptanediol-2,4, 2-ethylhexanediol-1,3, diethylene glycol, dipropylene glycol, triethylene glycol, tripropylene glycol, glycerin, etc.; a ketone-based solvent such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, fenchone, etc.; an ether-based solvent such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, propylene glycol monomethyl ether acetate, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, etc.; an ester-based solvent such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, diethyl phthalate, etc.; a nitrogen-containing solvent such as N-methylformamide, N,N-dimethylformamide, N,N-diethylformamide, acetamide, N-methylacetamide, N,N-dimethylacetamide, N-methylpropionamide, N-methylpyrrolidone, etc.; a sulfur-containing solvent such as dimethyl sulfide, diethyl sulfide, thiophene, tetrahydrothiophene, dimethylsulfoxide, sulfolane, 1,3-propane sultone, etc. These solvents may be used one species alone or two or more species in combination.

In particular, a ketone-based solvent such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, fenchone, etc., are preferable in view of the preservation stability of the solution.

The heating temperature and heating time may optionally be selected. For example, a method of heating and stirring at 50° C. for 24 hours, a method of heating and stirring under reflux for 8 hours, etc. are included. Incidentally, as long as the compound represented by the average compositional formula (1) is hydrolyzed, it is also possible to use a method of stirring at room temperature without heating.

### Hydrolysis Condensate

The hydrolysis condensate of the compound represented by the average compositional formula (1) may be obtained by dissolving the compound represented by the average compositional formula (1) in a solvent containing water, subjecting the resultant solution to hydrolysis condensation reaction in the presence of a catalyst, and thereafter distilling off the solvent containing water, the catalyst, etc., from the reaction mixture under reduced pressure. Preferable catalyst includes, for example, an inorganic acid such as hydrochloric acid, nitric acid, etc., and an organic acid such as formic acid, oxalic acid, fumaric acid, maleic acid, glacial acetic acid, acetic anhydride, propionic acid, n-butyric acid, etc. The amount of the catalyst to be used ranges, for example, from 0.001% by mass to 1% by mass based on the total mass of the compound represented by the average compositional formula (1). The above-mentioned hydrolysis condensation reaction is carried out, for example, at a temperature condition of 30° C. to 80° C. The pH at the time of the above-mentioned hydrolysis condensation reaction is not particularly limited, and is generally 2 or more and less than 5. Also, as long as the effects of the present invention are not impaired, a compound other than the compound represented by the average compositional formula (1) may be added to give a hydrolysis cocondensate.

With reference to the above-mentioned hydrolysate condensate, the compound represented by the average compositional formula (1), the hydrolysate thereof, and the hydrolysis condensate thereof may be one species or two or more species, respectively. One species or two or more species from each of the compound represented by the average compositional formula (1), the hydrolysate thereof, and the hydrolysis condensate may be used in combination. Use of one species or two species is preferable.

Specific examples of the combination of two species of the above-mentioned hydrolysis condensates include the above-mentioned combination of the compounds represented by the average compositional formula (1).

The weight average molecular weight (Mw) of the above-mentioned hydrolysis condensate ranges from 1,000 to 50,000. The preferable weight average molecular weight ranges from 1,200 to 20,000. A condensate of the weight average molecular weight of 1,000 to 50,000 may be obtained. In addition, the above-mentioned hydrolysis condensate may be an oligomer having a weight average molecular weight of, for example, 300 to 999, for example, 300 to 1,000, for example, 300 to 2,000, and, for example, 300 to 3,000. The weight average molecular weight is a molecular weight obtained by GPC analysis in terms of polystyrene.

GPC analysis may be carried out by employing, for example, a GPC device (trade name: HLC-8220GPC, manufactured by TOSOH CORPORATION), and a GPC column (trade name: Shodex KF803L, KF802, KF801, manufactured by SHOWA DENKO K.K.), under the measurement conditions of a column temperature of 40° C., an eluent (elution solvent) of tetrahydrofuran, a flow amount (flow rate) of 1.0 ml/min, and polystyrenes (manufactured by SHOWA DENKO K.K.) as standard samples.

### Preparation of Coating Liquid

A coating liquid of the surface modifier according to the present invention contains a compound represented by the average compositional formula (1), a hydrolysate of the compound represented by the average compositional formula (1), or a hydrolysis condensate of the compound represented by the average compositional formula (1), and other components, if necessary, and the coating liquid may be prepared by dissolving these components in a suitable solvent(s). In the present invention, the preparation method thereof is not limited as long as such a coating liquid can be obtained. For example, each component may be successively added to the solvent to be used and mixed. In this case, the order of addition of each component is not particularly limited. Also, solutions of each component dissolved in a solvent used may be mixed.

Also, in the coating liquid of the present invention, an acid may be mixed in advance with the above-mentioned solution for the purpose of adjusting the pH thereof. The amount of the acid preferably ranges from 0.01 to 2.5 mole and more preferably from 0.1 to 2 mole based on 1 mole of the silicon atom of the compound represented by the average compositional formula (1).

The acid used above includes an inorganic acid such as hydrochloric acid, nitric acid, sulfuric acid and phosphoric acid; an organic acid including a monocarboxylic acid such as formic acid, acetic acid, malic acid, etc.; and a polyvalent carboxylic acid such as oxalic acid; citric acid, propionic acid, succinic acid, etc. Of these, an acid in the state of a solution may be used as it is, but it is preferable to use it after diluting with a solvent contained in a coating liquid. The other acids are preferably used by dissolving in a solvent of a coating liquid with a suitable concentration.

As the solvent, an organic solvent to be used for preparing the compound represented by the average compositional formula (1), the hydrolysate of the compound represented by the average compositional formula (1), or the hydrolysis condensate of the compound represented by the average compositional formula (1), as well as a solvent used for concentration, dilution or substitution with another solvent of these solutions may be used. The solvent may be used in one species alone or in combination of optionally selected more than one species.

The coating liquid of the present invention can be applied onto a substrate as it is to produce a cured film, because the coating liquid of the present invention contains the compound represented by the average compositional formula (1), the hydrolysate of the compound represented by the average compositional formula (1), or the hydrolysis condensate of the compound represented by the average compositional formula (1) in the above-mentioned solvent(s). In addition, for the purpose of adjusting the concentration, ensuring the flatness of the coating film, improving the wettability of the coating liquid to the substrate, adjusting the surface tension, polarity and boiling point of the coating liquid, etc., the above-mentioned solvent(s), and further other various solvents may be added and used as a coating liquid.

### Other Components

Other components that may be contained in the surface modifier are explained hereinbelow.

The surface modifier of the present invention may contain a curing catalyst. The curing catalyst acts as a curing catalyst at the time of heating and curing the coating film containing the hydrolysis condensate. As the curing catalyst, an ammonium salt, a phosphine, a phosphonium salt or a sulfonium salt may be used. Specific examples are as described in WO2017/145809.

Among them, a nitrogen-containing silane compound is preferable as the curing catalyst. The nitrogen-containing silane compound includes an imidazole ring-containing silane compound such as N-(3-triethoxysilylpropyl)-4,5-dihydroimidazole (IMIDTEOS), etc.

From the hydrolysis condensate (polymer) obtained by hydrolyzing the compound represented by the average compositional formula (1) in a solvent using a catalyst and condensing the same, the by-produced alcohol, the used hydrolysis catalyst and water may simultaneously be removed by distillation under reduced pressure, etc. In addition, the acid or base catalyst used for hydrolysis may be removed by neutralization or ion exchange. Further, to the surface modifier of the present invention may be added an organic acid, water, an alcohol, or a combination thereof for the purpose of stabilization of the surface modifier containing the hydrolysis condensate thereof.

The above-mentioned organic acid includes, for example, oxalic acid, acetic acid, trifluoroacetic acid, malonic acid, methylmalonic acid, succinic acid, maleic acid, malic acid, tartaric acid, phthalic acid, citric acid, glutaric acid, citric acid, lactic acid, salicylic acid, etc. Of these, oxalic acid, maleic acid, etc., are preferable. The organic acid is added in an amount of 0.1 to 5.0 parts by mass based on 100 parts by mass of the hydrolysis condensate of the compound represented by the average compositional formula (1). In addition, water to be used may be pure water, ultrapure water, deionized water, etc., and the water may be added in an amount of 1 to 20 parts by mass based on 100 parts by mass of the surface modifier. Also, the alcohol to be added is preferably one that is easily evaporated by heating after the application, and it includes, for example, methanol, ethanol, propanol, isopropanol, butanol, etc. The alcohol may be added in an amount of 1 to 20 parts by mass based on 100 parts by mass of the surface modifier.

Therefore, the surface modifier may contain one or more component selected from the group consisting of water, an acid, and a curing catalyst. The surface modifier of the present invention may contain, in addition to the above-mentioned components, an organic polymer compound, a photoacid generator and a surfactant, etc., if necessary.

The dry etching rate (the reduction in film thickness per unit time), attenuation coefficient and refractive index, etc., of the film formed from the surface modifier of the present invention may be adjusted by using an organic polymer compound.

The photoacid generator contained in the surface modifier of the present invention includes an onium salt compound, a sulfoneimide compound, and a disulfonyldiazomethane compound, etc. The onium salt compound includes an iodonium salt compound such as diphenyliodonium hexafluorophosphate, diphenyliodonium trifluoromethanesulfonate, diphenyliodonium nonafluoro-normal-butanesulfonate, diphenyliodonium perfluoro-normal-octanesulfonate, diphenyliodonium camphor sulfonate, bis(4-tert-butylphenyl)iodonium camphor sulfonate and bis(4-tert-butylphenyl)iodonium trifluoromethanesulfonate, etc., and a sulfonium salt compound such as triphenylsulfonium hexafluoroantimonate, triphenylsulfonium nonafluoro-normal-butanesulfonate, triphenylsulfonium camphorsulfonate and triphenylsulfonium trifluoromethanesulfonate, etc.

The sulfoneimide compound includes, for example, N-(trifluoro-methanesulfonyloxy)succinimide, N-(nonafluoro-normal-butanesulfonyloxy)succinimide, N-(camphorsulfonyloxy)succinimide and N-(trifluoromethanesulfonyloxy)naphthalimide, etc.

The disulfonyldiazomethane compound includes, for example, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl-diazomethane, etc.

The photoacid generator may be used in one species alone or in combination of two or more species. When the photoacid generator is used, the proportion thereof ranges from 0.01 to 15 parts by mass, or from 0.1 to 10 parts by mass, or from 0.5 to 1 parts by mass based on 100 parts by mass of the hydrolysis condensate of the compound represented by the average compositional formula (1).

The surfactant is effective in suppressing generation of pinholes and striation, etc., when the surface modifier of the present invention is applied onto the substrate. The surfactant contained in the surface modifier of the present invention includes, for example, a nonionic surfactant including a polyoxyethylene alkyl ether such as polyoxyethylene lauryl ether, polyoxyethylene stearyl ether, polyoxyethylene cetyl ether, polyoxyethylene oleyl ether, etc., a polyoxyethylene alkyl allyl ether such as polyoxyethylene octylphenol ether, polyoxyethylene nonylphenol ether, etc., a polyoxyethylene-polyoxypropylene block copolymer, a sorbitan fatty acid ester such as sorbitan monolaurate, sorbitan monopalmitate, sorbitan monostearate, sorbitan monooleate, sorbitan trioleate, sorbitan tristearate, etc., a polyoxyethylene sorbitan fatty acid ester such as polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate, etc., a fluorine-based surfactant such as EFTOP (Registered Trademark) EF301, EF303 and EF352 (available from TORKEM PRODUCTS Corporation), MEGAFACE (Registered Trademark) F171, F173, R-08, R-30, R-30N and R-40LM (available from DIC Corporation), Fluorad (Registered Trademark) FC430 and FC431 (available from Sumitomo 3M Limited), AsahiGuard (Registered Trademark) AG710, Surflon (Registered Trademark) S-382, SC101, SC102, SC103, SC104, SC105 and SC106 (available from Asahi Glass Co., Ltd.), etc., and organosiloxane polymer KP341 (available from Shin-Etsu Chemical Co., Ltd.), etc. The surfactant may be used alone or in combination of two or more. When the surfactant is used, the proportion thereof ranges from 0.0001 to 5 parts by mass, or from 0.001 to 1 part by mass, or from 0.01 to 1 part by mass based on 100 parts by mass of the hydrolysis condensate of the compound represented by the average compositional formula (1).

Also, to the surface modifier of the present invention, a rheology modifier and an adhesive adjuvant, etc., may be added. The rheology modifier is effective for improving fluidity of the surface modifier. The adhesive adjuvant is effective for improving adhesion between the underlayer film and the semiconductor substrate or resist.

The solvent used for the surface modifier of the present invention may be used without any particular limitation as long as it is a solvent capable of dissolving the above-mentioned solid components. Such a solvent includes, for example, water (deionized water, ultrapure water), methyl cellosolve acetate, ethyl cellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propionate propyl, propionate isopropyl, propionate butyl, propionate isobutyl, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutylpropionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone, etc. These solvents may be used alone, or in combination of two or more.

Preferable solvents are propylene glycol monomethyl ether acetate, propylene glycol monoethyl ether, propylene glycol monomethyl ether, and ultrapure water.

The surface modifier according to the present invention can be applied onto an oxide film and a nitride film such as SiO₂, SiN, SiON, TiN, etc., and a metal substrate in addition to Bare-Si and others. The above-mentioned substrate is preferably a metal or an inorganic-based antireflection film substrate. The above-mentioned substrate is preferably Si, SiN, SiON, TiSi, TiN or glass which may vapor-deposited by Cr.

Further, the surface modifier according to the present invention can be applied onto a coating-type or a vapor deposition-type SiHM, onto BARC, a coating type SOC (spin-on carbon, a film having a high carbon content), or onto a vapor deposition type amorphous carbon.

### Laminated Substrate

A laminated substrate, which comprises a substrate, the surface modifier according to the present invention laminated on the substrate, and a resist pattern laminated on the laminated surface modifier, can be obtained. Preferably, the laminated substrate further comprises a silicon hard mask layer on the substrate. Optionally, the above-mentioned spin-on carbon layer or an amorphous carbon layer may further be formed under the above-mentioned silicon hard mask layer.

The film thickness of the silicon hard mask layer, the spin-on carbon layer and the amorphous carbon layer range, for example, from 5 nm to 2,000 nm.

### Method for Forming a Resist Pattern and Method for Manufacturing a Semiconductor Device

A pattern may be formed by applying the surface modifier according to the present invention onto a substrate, baking the applied surface modifier, applying a photoresist composition onto the baked surface modifier and subjecting the photoresist composition-applied substrate to patterning. Preferably, the method further comprises the step of modifying the baked substrate with a solvent after the step of baking the applied surface modifier and before the step of applying a photoresist composition onto the baked surface modifier. Preferably, the step of patterning comprises the step of exposing the photoresist composition-applied substrate with ArF, EUV or EB. More preferably, the exposure is with EUV (wavelength 13.5 nm) or EB (electron beam), and most preferably with EUV (wavelength 13.5 nm).

The above-mentioned pattern is preferably a resist pattern.

The method for manufacturing a semiconductor device according to the present invention comprises the steps of applying the surface modifier according to the present invention onto a substrate, baking the applied surface modifier, applying a photoresist composition onto the baked surface modifier, subjecting the photoresist composition-applied substrate to patterning, and etching the patterned substrate.

The surface modifier according to the present invention is applied to a substrate to make a coating film. The application is carried out by any of the conventional methods such as spin coating, etc. The coating film is baked, and then the step of applying a photoresist composition is applied thereon to form a resist may be conducted. The temperature and time for the baking range usually from 80 to 300° C. and from 0.5 to 5 minutes, respectively.

After the formation of the coating film of the surface modifier of the present application, the method may further comprise the step of treating the coating film with a solvent before the application of the photoresist composition. As the solvent used for this purpose, a solvent used for a photoresist composition is used. Examples of usable solvents include methyl cellosolve acetate, ethyl cellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutylpropionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone. Propylene glycol monomethyl ether, propylene glycol monomethyl ether acetate and cyclohexanone are preferable. After coating the solvent by any of the conventional methods such as spin coating, etc., the film may be heated to 80° C. to 200° C. to dry the solvent.

It is also possible that a coating film is prepared by coating the surface modifier according to the present invention onto the substrate, and after baking the film, a hard mask comprising silicon is formed thereon, and a resist can be formed thereon.

The surface modifier according to the present invention may form a film having a film thickness of 1 nm to 1,000 nm on a semiconductor substrate. The film thickness ranges, for example, from 1 nm to 500 nm, from 0.1 nm to 500 nm, from 0.1 nm to 300 nm, from 0.1 nm to 200 nm, from 0.1 nm to 100 nm, from 0.1 nm to 50 nm, from 0.1 nm to 30 nm, from 0.1 nm to 20 nm, from 0.1 nm to 10 nm, and most preferably from 0.1 nm to 8 nm.

Polysiloxanes obtained by hydrolyzing hydrolyzable silanes may be used as the above-mentioned hard mask comprising silicon. For example, a polysiloxane obtained by hydrolyzing tetraethoxysilane, methyltrimethoxysilane, and phenyltriethoxysilane may be exemplified. These polysiloxanes may form a film onto the coating film of the surface modifier according to the present invention with a film thickness of 5 to 200 nm.

The above-mentioned the photoresist composition is not particular limited as long as it is sensitive to the light used for exposure. Either of a negative type photoresist or a positive type photoresist may be used. The photoresist includes a positive type photoresist comprising a novolac resin and 1,2-naphthoquinonediazide sulfonic acid ester, a chemical amplification type photoresist comprising a binder having a group that decomposes with an acid to increase an alkali dissolution rate and a photoacid generator, a chemical amplification type photoresist comprising a low molecular compound that decomposes with an acid to increase an alkali dissolution rate of the photoresist, an alkali soluble binder and a photoacid generator, and a chemical amplification type photoresist comprising a binder having a group that decomposes with an acid to increase an alkali dissolution rate, a low molecular compound that decomposes with an acid to increase an alkali dissolution rate of the photoresist and a photoacid generator, etc. For example, the photoresist includes trade name: APEX-E available from Shipley Company L.L.C., trade name: PAR710 available from Sumitomo Chemical Company Limited, and trade name: SEPR430 available from Shin-Etsu Chemical Co., Ltd., etc. In addition, there includes, for example, a fluorine atom-containing polymer-based photoresist as disclosed in Proc. SPIE, Vol. 3999, 330-334 (2000), Proc. SPIE, Vol. 3999, 357-364 (2000), and Proc. SPIE, Vol. 3999, 365-374 (2000).

Also, as the electron beam resist, either of a negative type or a positive type may be used. The electron beam resist includes a chemical amplification type resist comprising an acid generator and a binder having a group that decomposes with an acid to change an alkali dissolution rate, a chemical amplification type resist comprising an alkali soluble binder, an acid generator and a low molecular compound that decomposes with an acid to change an alkali dissolution rate of the resist, a chemical amplification type resist comprising an acid generator, a binder having a group that decomposes with an acid to change an alkali dissolution rate and a low molecular compound that decomposes with an acid to change an alkali dissolution rate of the resist, a non-chemical amplification type resist comprising a binder having a group that decomposes with an electron beam to change an alkali dissolution rate, and a non-chemical amplification type resist comprising a binder having a site that is cleaved by an electron beam to change an alkali dissolution rate, etc. Even when these electron beam resists are used, a resist pattern may be formed with an irradiation source as an electron beam similarly in the case of using a photoresist.

After coating the resist solution, baking is carried out at a baking temperature of 70 to 150° C. for a baking time of 0.5 to 5 minutes to obtain a resist film with a thickness within the range of 10 to 1,000 nm. For example, the thickness may be 10 to 50 nm for EUV light (wavelength 13.5 nm) or electron beam, and 50 to 200 nm, preferably 100 to 150 nm for ArF excimer laser (wavelength 193 nm). The surface modifier according to the present invention, a resist solution, a developing solution, etc., may be allowed to cover by spin coating, a dipping method, a spray method, etc., and the spin coating method is particularly preferable. Exposure of the resist is carried out through a predetermined mask. For the exposure, KrF excimer laser (wavelength 248 nm), ArF excimer laser (wavelength 193 nm) and EUV light (wavelength 13.5 nm), electron beam, etc., may be used. After the exposure, if necessary, post exposure bake (PEB) may also be carried out. The post exposure bake conditions are appropriately selected from a heating temperature of 70° C. to 150° C. and a heating time of 0.3 to 10 minutes.

Then, the development may be carried out with a developing solution. Thereby, when a positive type photoresist is used, for example, the photoresist at the exposed portion is removed to form a pattern of the photoresist.

As the developing solution, an aqueous solution of an alkali metal hydroxide such as potassium hydroxide, sodium hydroxide, etc., an aqueous solution of a quaternary ammonium hydroxide such as tetramethylammonium hydroxide, tetraethylammonium hydroxide, choline, etc., an alkaline aqueous solution such as an aqueous amine solution of ethanolamine, propylamine, ethylenediamine, etc., may be exemplified. Further, a surfactant, etc., may be added to these developing solutions. The conditions of the development may appropriately be selected from a temperature of 5 to 50° C. and a time of 10 to 600 seconds. In addition, in the present invention, an organic solvent may be used as the developing solution.

Examples of the organic solvent includes, for example, methyl acetate, butyl acetate, ethyl acetate, isopropyl acetate, amyl acetate, isoamyl acetate, ethyl methoxy acetate, ethyl ethoxy acetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, etc.

The resist pattern may be removed by etching to invert the pattern. Dry etching may be carried out using a gas such as tetrafluoromethane, perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride and chlorine trifluoride, etc. It is particularly preferable to carry out the dry etching with an oxygen-based gas.

Using as a protective film a photoresist film (upper layer) to which a pattern has been formed as explained above, a silicon hard mask (intermediate layer) formed in the lower layer of the surface modifier of the present invention is removed by etching, etc., to carry out patterning. Then, using as a protective film the film comprising the patterned photoresist film (upper layer) and the silicon hard mask (intermediate layer), an organic film (lower layer) such as spin-on carbon or amorphous carbon, etc., is removed to carry out patterning. Finally, using as a protective film the patterned silicon hard mask (intermediate layer) and the above-mentioned organic film (lower layer), processing of the semiconductor substrate is carried out.

Also, when the above-mentioned organic film is not formed onto the substrate, the film comprising the patterned photoresist and the above-mentioned organic film (intermediate layer) is used as a protective film, processing of a semiconductor substrate is carried out.

After the photoresist film is patterned, the silicon hard mask (intermediate layer) at the portion at which the photoresist film has been removed is firstly removed by dry etching to expose the above-mentioned organic film (lower layer). For dry etching the silicon hard mask, a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride and chlorine trifluoride, chlorine, trichloroborane and dichloroborane, etc., may be used. It is preferable to use a halogen-based gas for dry etching of the silicon hard mask. In the dry etching by the halogen-based gas, a photoresist film essentially consisting of organic substances or the above-mentioned organic film is basically difficultly removed. To the contrary, the silicon hard mask containing a large amount of silicon atoms is rapidly removed by the halogen-based gas. Therefore, it is possible to suppress the reduction in film thickness of the photoresist accompanied by dry etching of the silicon hard mask. And as a result, it becomes possible to use the photoresist with a thin film.

Dry etching of the silicon hard mask is preferably carried out by a fluorine-based gas, and the fluorine-based gas includes, for example, tetrafluoromethane (CF₄), perfluorocyclobutane (C₄F₈), perfluoropropane (C₃F₈), trifluoromethane, and difluoromethane (CH₂F₂), etc.

Thereafter, using as a protective film the patterned photoresist film and the silicon hard mask, removal of the organic underlayer film is carried out. For the above-mentioned organic film (lower layer), it is preferably carried out by dry etching using an oxygen-based gas. This is because the silicon hard mask containing a large amount of silicon atoms is difficultly removed by dry etching using an oxygen-based gas.

In addition, by removing the resist pattern, it is also possible to form a reverse pattern (inversion pattern) of the compound represented by the average compositional formula (1), the hydrolysate thereof, or the hydrolysis condensate thereof contained in the surface modifier according to the present invention.

### EXAMPLES

Hereinafter, the present invention will be explained in more detail by referring to Examples, etc., but the present invention is not limited to the following embodiments.

### Preparation of Coating Liquid

Each of Si-containing monomers having Formula-1 to Formula-22 and a Si-containing polymer (Mw=2300) having Formula 23 was dissolved in a solvent with a proportion shown in Table 1 to obtain the preparation liquids of Preparation Examples 1 to 23.

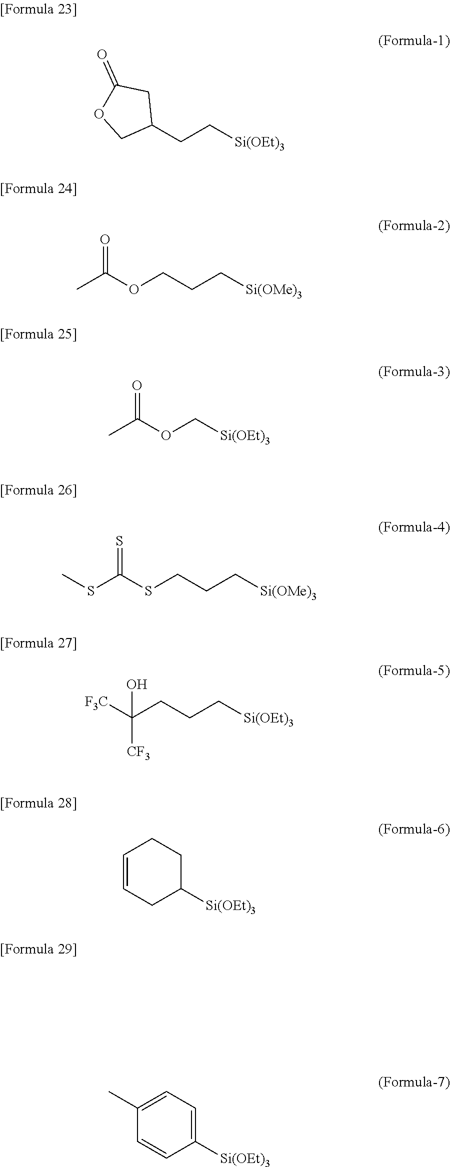

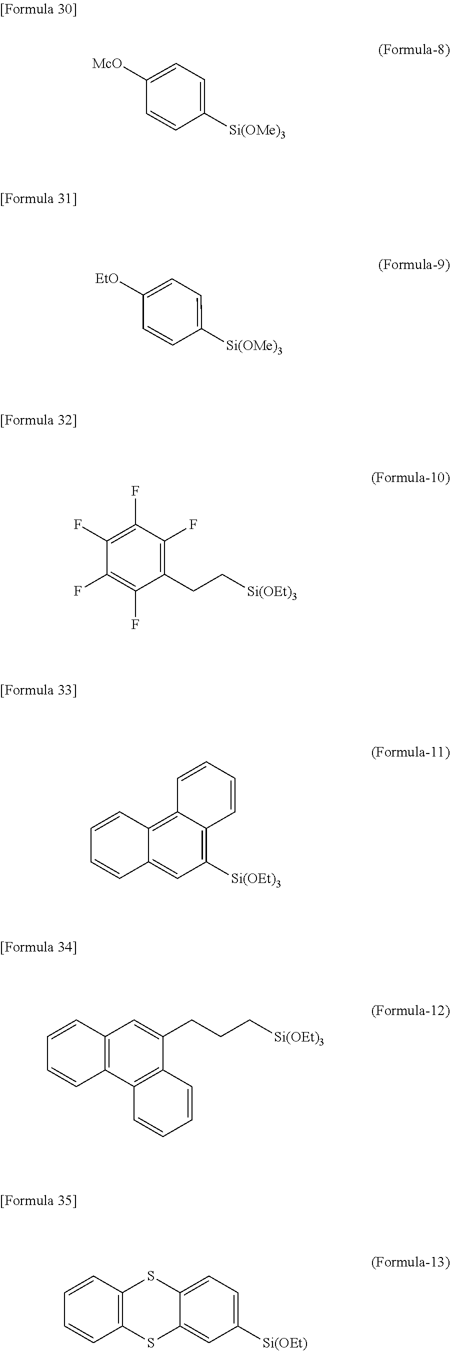

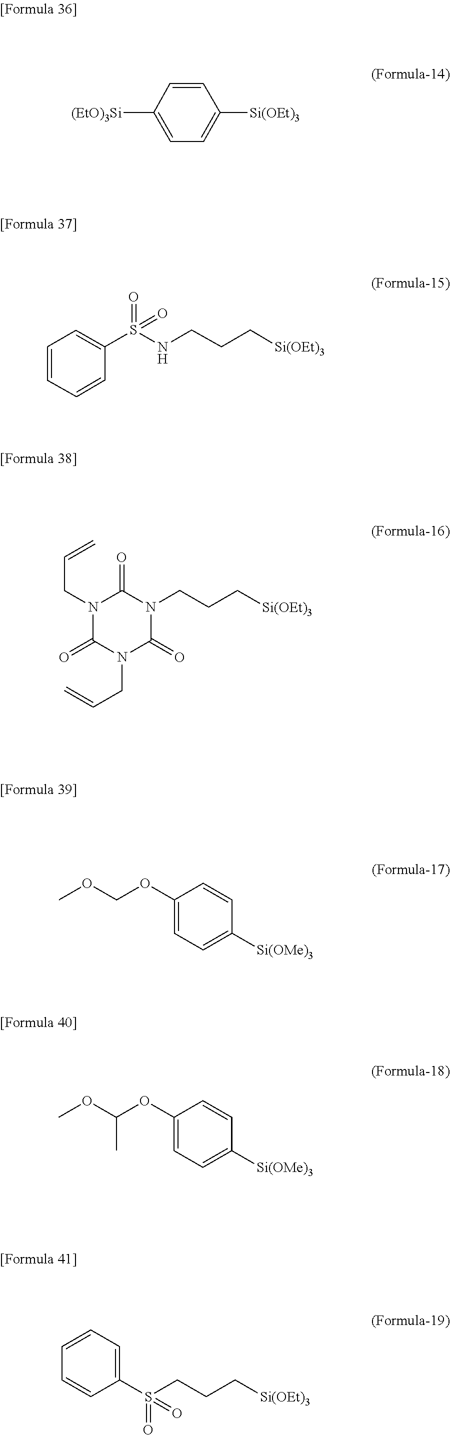

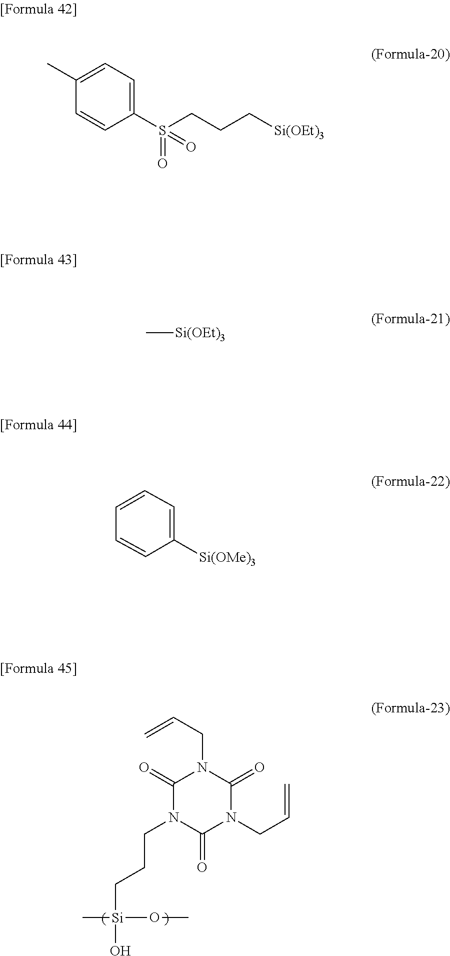

In Table 1, propylene glycol monomethyl ether acetate was abbreviated to as PGMEA, propylene glycol monoethyl ether as PGEE, propylene glycol monomethyl ether as PGME, and ultrapure water as DIW. Also, the content ratio of each component is expressed by parts by mass.

TABLE 1

| Prepara- | Species of | Content ratio (parts by mass) | | | | |
|---|---|---|---|---|---|---|
| tion | surface | Surface | Solvent | | | |
| Example | modifier | modifier | PGEE | PGMEA | PGME | DIW |
| 1 | Formula-1 | 0.10 | 75 | 12 | 5 | 8 |
| 2 | Formula-2 | 0.10 | 75 | 12 | 5 | 8 |
| 3 | Formula-3 | 0.10 | 75 | 12 | 5 | 8 |
| 4 | Formula-4 | 0.10 | 75 | 12 | 5 | 8 |
| 5 | Formula-5 | 0.10 | 75 | 12 | 5 | 8 |
| 6 | Formula-6 | 0.10 | 75 | 12 | 5 | 8 |
| 7 | Formula-7 | 0.10 | 75 | 12 | 5 | 8 |
| 8 | Formula-8 | 0.10 | 75 | 12 | 5 | 8 |
| 9 | Formula-9 | 0.10 | 75 | 12 | 5 | 8 |
| 10 | Formula-10 | 0.10 | 75 | 12 | 5 | 8 |
| 11 | Formula-11 | 0.10 | 75 | 12 | 5 | 8 |
| 12 | Formula-12 | 0.10 | 75 | 12 | 5 | 8 |
| 13 | Formula-13 | 0.10 | 75 | 12 | 5 | 8 |
| 14 | Formula-14 | 0.10 | 75 | 12 | 5 | 8 |
| 15 | Formula-15 | 0.10 | 75 | 12 | 5 | 8 |
| 16 | Formula-16 | 0.10 | 75 | 12 | 5 | 8 |
| 17 | Formula-17 | 0.10 | 75 | 12 | 5 | 8 |
| 18 | Formula-18 | 0.10 | 75 | 12 | 5 | 8 |
| 19 | Formula-19 | 0.10 | 75 | 12 | 5 | 8 |
| 20 | Formula-20 | 0.10 | 75 | 12 | 5 | 8 |
| 21 | Formula-21 | 0.10 | 75 | 12 | 5 | 8 |
| 22 | Formula-22 | 0.10 | 75 | 12 | 5 | 8 |
| 23 | Formula-23 | 0.10 | 75 | 12 | 5 | 8 |

Next, as shown in Table 2, a pH adjusting agent and a curing catalyst were added to each of the preparation examples to obtain coating liquids 1 to 23. The pH adjusting agent was maleic acid, and the curing catalyst used was shown in the following Formula-24. The content ratio of each component is expressed by parts by mass.

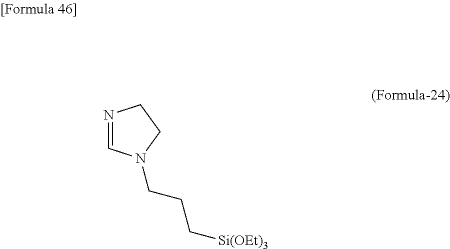

TABLE 2

| | | Content ratio (parts by mass) | | |
|---|---|---|---|---|
| | | | pH adjusting | Curing |
| Coating | Prepared | | agent | catalyst |
| solution | liquid | Prepared liquid | (maleic acid) | (Formula-24) |
| 1 | Preparation | 100 | 0.01 | 0.00005 |
| | Example 1 | | | |
| 2 | Preparation | 100 | 0.01 | 0.00005 |
| | Example 2 | | | |
| 3 | Preparation | 100 | 0.01 | 0.00005 |
| | Example 3 | | | |
| 4 | Preparation | 100 | 0.01 | 0.00005 |
| | Example 4 | | | |
| 5 | Preparation | 100 | 0.01 | 0.00005 |
| | Example 5 | | | |
| 6 | Preparation | 100 | 0.01 | 0.00005 |
| | Example 6 | | | |
| 7 | Preparation | 100 | 0.01 | 0.00005 |
| | Example 7 | | | |
| 8 | Preparation | 100 | 0.01 | 0.00005 |
| | Example 8 | | | |
| 9 | Preparation | 100 | 0.01 | 0.00005 |
| | Example 9 | | | |
| 10 | Preparation | 100 | 0.01 | 0.00005 |
| | Example 10 | | | |
| 11 | Preparation | 100 | 0.01 | 0.00005 |
| | Example 11 | | | |
| 12 | Preparation | 100 | 0.01 | 0.00005 |
| | Example 12 | | | |
| 13 | Preparation | 100 | 0.01 | 0.00005 |
| | Example 13 | | | |
| 14 | Preparation | 100 | 0.01 | 0.00005 |
| | Example 14 | | | |
| 15 | Preparation | 100 | 0.01 | 0.00005 |
| | Example 15 | | | |
| 16 | Preparation | 100 | 0.01 | 0.00005 |
| | Example 16 | | | |
| 17 | Preparation | 100 | 0.01 | 0.00005 |
| | Example 17 | | | |
| 18 | Preparation | 100 | 0.01 | 0.00005 |
| | Example 18 | | | |
| 19 | Preparation | 100 | 0.01 | 0.00005 |
| | Example 19 | | | |
| 20 | Preparation | 100 | 0.01 | 0.00005 |
| | Example 20 | | | |
| 21 | Preparation | 100 | 0.01 | 0.00005 |
| | Example 21 | | | |
| 22 | Preparation | 100 | 0.01 | 0.00005 |
| | Example 22 | | | |
| 23 | Preparation | 100 | 0.01 | 0.00005 |
| | Example 23 | | | |

In the following, the evaluation results using the coating liquids of the invention of the present application are shown.

### Substrate Surface Adhesion

Each of the coating liquids 1 to 23 was coated onto a Bare-Si wafer. Specifically, using CLEANTRACK (Registered Trademark) ACT8 (Tokyo Electron), 1 ml of each of the coating liquids 1 to 23 was applied to the wafer, subjected to spin coating at 1,500 rpm for 60 seconds, and then, baked at 110° C. Adhesion of the materials to the surface of substrate was evaluated by measuring the film thickness of the coating films formed by the coating liquids 1 to 23 on the Bare-Si substrate. The material film thickness was determined by using Ellipsometric Film Thickness Measurement System RE-3100 (SCREEN). Also, as Comparative Example 1, the film thickness of the natural oxide film on the Bare-Si wafer was measured for comparison. The measurement results are described in the following Table 3.

TABLE 3

| | Substrate | Coating film | Film thickness (Å) |
|---|---|---|---|
| Example 1 | Bare-Si | Coating liquid 1 | 13 |
| Example 2 | Bare-Si | Coating liquid 2 | 22 |
| Example 3 | Bare-Si | Coating liquid 3 | 11 |
| Example 4 | Bare-Si | Coating liquid 4 | 25 |
| Example 5 | Bare-Si | Coating liquid 5 | 11 |
| Example 6 | Bare-Si | Coating liquid 6 | 11 |
| Example 7 | Bare-Si | Coating liquid 7 | 18 |
| Example 8 | Bare-Si | Coating liquid 8 | 19 |
| Example 9 | Bare-Si | Coating liquid 9 | 20 |
| Example 10 | Bare-Si | Coating liquid 10 | 14 |
| Example 11 | Bare-Si | Coating liquid 11 | 31 |
| Example 12 | Bare-Si | Coating liquid 12 | 11 |
| Example 13 | Bare-Si | Coating liquid 13 | 28 |
| Example 14 | Bare-Si | Coating liquid 14 | 17 |
| Example 15 | Bare-Si | Coating liquid 15 | 37 |
| Example 16 | Bare-Si | Coating liquid 16 | 30 |
| Example 17 | Bare-Si | Coating liquid 17 | 16 |
| Example 18 | Bare-Si | Coating liquid 18 | 15 |
| Example 19 | Bare-Si | Coating liquid 19 | 25 |
| Example 20 | Bare-Si | Coating liquid 20 | 20 |
| Example 21 | Bare-Si | Coating liquid 21 | 22 |
| Example 22 | Bare-Si | Coating liquid 22 | 31 |
| Example 23 | Bare-Si | Coating liquid 23 | 46 |
| Comparative | Bare-Si | None | 10 |
| Example 1 | | | |

### Substrate Surface Modification

Each of the coating liquids 1 to 23 was coated onto the Bare-Si and SiON (50 nm). Specifically, using CLEANTRACK (Registered Trademark) ACT8 (Tokyo Electron), 1 ml of each of the coating liquids 1 to 23 was coated onto a wafer, subjected to spin coating at 1,500 rpm for 60 seconds, and then, baked at 110° C. The contact angle of water was determined for the Bare-Si substrate bearing a coating films formed by each of the coating liquids 1 to 23. Measurement of the water contact angle was carried out in a constant temperature and humidity environment (23° C.±2° C., 45% RH±5%) using a fully automatic contact angle meter DM-701 (manufactured by Kyowa Interface Science Inc.) with a liquid amount of 3 μl and measured after allowing to stand after the landing of the liquid for 5 seconds. The measurement results are shown in the following Table 4.

TABLE 4

| | | | Water contact angle |
|---|---|---|---|
| | Substrate | Coating film | (°) |
| Example 24 | Bare-Si | Coating liquid 1 | 19 |
| Example 25 | Bare-Si | Coating liquid 2 | 12 |
| Example 26 | Bare-Si | Coating liquid 3 | 22 |
| Example 27 | Bare-Si | Coating liquid 4 | 38 |
| Example 28 | Bare-Si | Coating liquid 5 | 11 |
| Example 29 | Bare-Si | Coating liquid 6 | 17 |
| Example 30 | Bare-Si | Coating liquid 7 | 18 |
| Example 31 | Bare-Si | Coating liquid 8 | 15 |
| Example 32 | Bare-Si | Coating liquid 9 | 21 |
| Example 33 | Bare-Si | Coating liquid 10 | 22 |
| Example 34 | Bare-Si | Coating liquid 11 | 42 |
| Example 35 | Bare-Si | Coating liquid 12 | 21 |
| Example 36 | Bare-Si | Coating liquid 13 | 28 |
| Example 37 | Bare-Si | Coating liquid 14 | 39 |
| Example 38 | Bare-Si | Coating liquid 15 | 25 |
| Example 39 | Bare-Si | Coating liquid 16 | 62 |
| Example 40 | Bare-Si | Coating liquid 17 | 22 |
| Example 41 | Bare-Si | Coating liquid 18 | 14 |
| Example 42 | Bare-Si | Coating liquid 19 | 50 |
| Example 43 | Bare-Si | Coating liquid 20 | 56 |
| Example 44 | Bare-Si | Coating liquid 21 | 28 |
| Example 45 | Bare-Si | Coating liquid 22 | 30 |
| Example 46 | Bare-Si | Coating liquid 23 | 64 |
| Example 47 | SiON | Coating liquid 16 | 50 |
| Comparative | Bare-Si | None | 16 |
| Example 2 | | | |
| Comparative | SiON | None | 22 |
| Example 3 | | | |

### EUV Patterning

The coating liquid 16 was coated onto SiON (50 nm), and a photoresist was formed onto the wafer bearing a film formed by the coating liquid 16. As the photoresist, EUV-PR (EUV-photoresist) manufactured by JSR was used. Patterning evaluation was carried out using an EUV exposure machine. The exposure was carried out using NXE3300 (manufactured by ASML), and the observation was carried out by SEM (CG4100, manufactured by HITACHI). The evaluation results are shown in Table 5. In Table 5, when the SEM observation showed a pattern collapse caused in the photoresist, the result was reported as pattern collapse, and when the SEM observation showed no pattern collapse caused in the photoresist and the intended pattern formed, the result was reported as being good. Also, Comparative Example 4 in the Table shows the results of HMDS treatment to a SiON wafer under the conditions of 100° C. for 60 seconds followed by patterning using an EUV exposure machine.

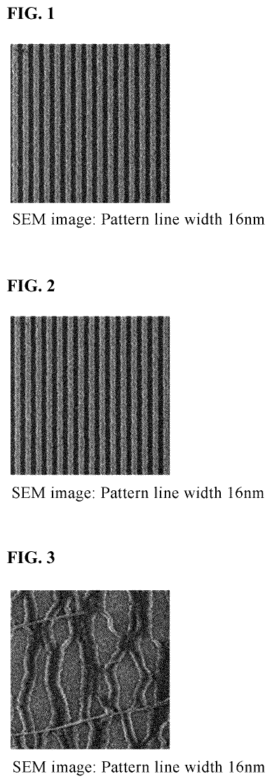

TABLE 5

| | Pattern | Substrate | Baking | Patterning | Draw- |
|---|---|---|---|---|---|
| | size (nm) | treatment | temperature (°) | result | ing |
| Example 48 | 16 | Coating | 110 | Good | FIG. 1 |
| | | liquid 16 | | | |
| Example 49 | 16 | Coating | 240 | Good | FIG. 2 |
| | | liquid 16 | | | |
| Comparative | 16 | HMDS | — | Pattern | FIG. 3 |
| Example 4 | | | | collapse | |

### EB Patterning

Each of the coating liquids 19 and 20 was coated onto SiON (50 nm), and a photoresist was formed onto the wafer bearing a film formed by each of the coating liquids 19 and 20, respectively. As the photoresist, EUV-PR manufactured by TOK was used. Drawing was carried out using an EB drawing machine ELS-G130 (manufactured by ELIONIX INC.), and observation by SEM (CG4100, manufactured by HITACHI) was carried out. The evaluation results are shown in Table 6. In Table 6, when the SEM observation showed a pattern collapse caused in the photoresist, the result was reported as pattern collapse, and when the SEM observation showed an intended pattern formed, the result was reported as being good. Also, Comparative Example 5 in the Table shows the results of the HMDS treatment to the SiON wafer under the conditions of 100° C. for 60 seconds followed by patterning using an EUV exposure machine.

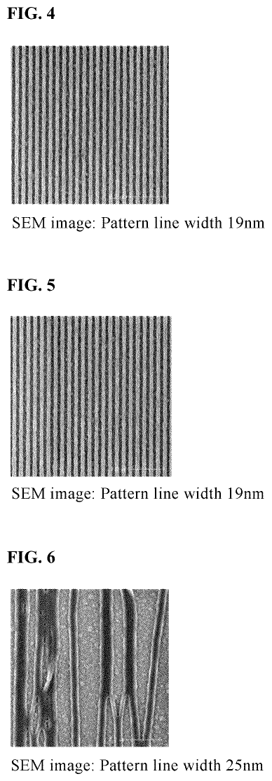

TABLE 6

| | Pattern | Substrate | Baking | Patterning | Draw- |
|---|---|---|---|---|---|
| | size (nm) | treatment | temperature (°) | result | ing |
| Example 50 | 19 | Coating | 110 | Good | FIG. 4 |
| | | liquid 19 | | | |
| Example 51 | 19 | Coating | 110 | Good | FIG. 5 |
| | | liquid 20 | | | |
| Comparative | 25 | HMDS | — | Pattern | FIG. 6 |
| Example 5 | | | | collapse | |

### INDUSTRIAL APPLICABILITY

Modification of the surface of a wafer using the silane coupling agent improves adhesiveness of the photoresist, and improves photoresist resolution in advanced lithography processes. Moreover, because the film thickness of the silane coupling agent is thinner than that of the conventional underlayer films, an advantageous effect of suppressing etching failure such as side etching, etc., during the etching step is brought about.

1. A process for making a substrate having a resist pattern with 0.10 μm or less, comprising:
providing a substrate optionally carrying a silicon hard mask layer thereon,
applying a surface modifier on a surface of one of the substrate or a silicon hard mask layer on the substrate,
baking the applied surface modifier to provide a coating film having a thickness of 4.6 nm or less,
applying a photoresist composition onto the baked coating film, and
patterning the photoresist composition-applied substrate by exposing the photoresist composition-applied substrate with ArF, EUV or EB;
wherein the surface modifier comprises at least one species of a compound represented by the following average compositional formula (1), a hydrolysate of the compound represented by the following average compositional formula (1), and a hydrolysis condensate of the compound represented by the following average compositional formula (1):
R¹ₐR²_{b}(OX)_{c}SiO_{(4-a-b-c)/2} (1)
wherein
R¹ is a monovalent organic group represented by the general formula: —(CH₂)ₙY, in which Y represents a hydrogen atom, an acetoxy group, a γ-butyrolactone group, a C1 to C6 carbinol group which may be substituted with a halogen atom(s), a norbornene group, a tolyl group, C1 to C3 alkoxyphenyl group, a C6 to C30 aryl group which may be substituted with a halogen atom(s) or a C1 to C3 alkoxysilyl group, a C1 to C4 alkyl group which may be interrupted by an oxygen atom, a phenylsulfonamide group, a monovalent group derived from cyclic amide which may be substituted with a C1 to C3 alkyl group or a C2 to C5 alkenyl group, a monovalent group derived from cyclic imide which may be substituted with a C1 to C3 alkyl group or a C2 to C5 alkenyl group, a C3 to C6 cyclic alkenyl group which may be substituted with a C1 to C3 alkyl group or a C2 to C5 alkenyl group, a phenylsulfone group, a p-tolylsulfonyl group, a p-toluenesulfonyl group or a monovalent group represented by the following formula (1-1) or (1-2), 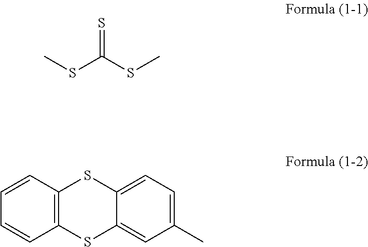
n is an integer of 0 to 4,
R² is a C1 to 4 monovalent hydrocarbon group,
X represents a hydrogen atom or a C1 to 4 monovalent hydrocarbon group,
a is a number of 1 to 2,
b is a number of 0 to 1,
c is a number of 0 to 2, and
a+b+c≤4.

2. The process according to claim 1, wherein R¹ is an acetoxy group, a γ-butyrolactone group, a di(trifluoromethyl)hydroxymethyl group, a cyclohexenyl group, a tolyl group, a C1 to C3 alkoxyphenyl group, a pentafluorophenyl group, a phenanthrenyl group, a C1 to C3 alkoxysilylphenyl group, a phenylsulfonamide group, or a monovalent group represented by the following formula (1-1), (1-2) or (1-3):

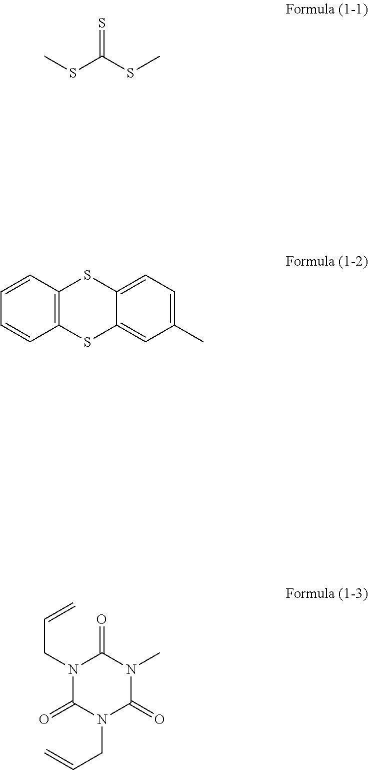

3. The process according to claim 1, wherein the substrate is a metal or an inorganic-based antireflection film substrate.

4. The process according to claim 1, wherein the substrate contains Si, SiN, SiON, TiSi, TiN or glass which may be vapor-deposited by Cr.

5. A method for manufacturing a semiconductor device, which comprises:
making a substrate having a resist pattern with 0.10 μm or less by the process according to claim 1.
